(19) United States
(12) Patent Application Publication
(10) Pub. No.: US 2011/0073347 A1
(43) Pub. Date: Mar. 31, 2011

(54) Electrical cover

(76) Inventor: Neil Edward Boa, Calgary (CA)

(21) Appl. No.: 12/585,983

(22) Filed: Sep. 30, 2009

(51) Int. Cl. H05K 5/03

(52) U.S. Cl. 174/66

(57) ABSTRACT

Disclosed is a cover for an electrical interface. The electrical interface may be a rocker type switch located within a hole in a wall. The cover is sized to cover the hole in the wall and has an aperture therethrough sized to surround the rocker type switch. The cover further comprises a rocker plate sized to overlay the rocker type switch pivotally located within the aperture wherein the rocker plate bears against the rocker type switch so as to transmit motion of the rocker plate to the rocker type switch. The electrical interface may be an electrical receptacle wherein the cover has front and rear surfaces and a hollowed region in the rear surface sized to receive the electrical receptacle therein. The cover further comprises a plurality of apertures located through the cover plate sized and located to correspond to the connector openings.

### BACKGROUND OF THE INVENTION

1. Field of Invention

The present invention relates to covers in general and in particular to covers for electrical outlets and switches.

2. Description of Related Art

Electrical outlets and wall switches are typically installed within a hole in a wall or more commonly within a receptacle or switch electrical box. The electrical box may be secured to a wall member such as a stud or directly to the drywall in which the hole is provided. Such outlets and switches typically have a cover provided to cover the remainder of the hole in the wall corresponding to the electrical box.

It is well known that people often desire to change the look of their electrical outlets and switches from time to time. Such desire can arise from a wish to replace an outlet that is worn or dirty or to change the appearance of the decorating within the room. In such cases, one method has been to replace the cover only. Such covers however typically only replace the existing cover whereas the old switch or receptacle will remain. In such cases where the old switch or receptacle has an undesirable appearance, the options available to the owner are to accept the appearance of the old switch or to replace the entire switch or receptacle. This is undesirable and difficult for many home owners to accomplish by themselves without hiring an electrician to perform for them.

### SUMMARY OF THE INVENTION

According to a first embodiment of the present invention there is disclosed a cover for a rocker type switch located within a hole in a wall comprising a cover plate sized to cover the hole in the wall. The cover plate has an aperture therethrough sized to surround the rocker type switch. The cover further comprises a rocker plate sized to overlay the rocker type switch pivotally located within the aperture wherein the rocker plate bears against the rocker type switch so as to transmit motion of the rocker plate to the rocker type switch.

The aperture may have a rectangular shape corresponding to a rectangular outline of the rocker type switch. The rocker plate may have first and second planar segments angularly oriented relative to each other. The second planar segment may be oriented out of a plane of the first planar segment by an angle corresponding to the rocker type switch.

The cover may further comprise a pivot between the cover plate and the rocker plate. The pivot may comprise a pair of opposed pins extending from the rocker plate wherein the aperture of the cover plate has a pair of bores sized to receive the pins therein. The bores may be located in plates extending perpendicularly from the aperture. The bores may be located adjacent to opposed sides of the angle. The cover plate may have first and second mounting bores sized and located to receive screws therethrough to secure the cover to the wall.

According to a further embodiment of the present invention there is disclosed a cover for an electrical receptacle having a plurality of connector openings located within a hole in a wall. The cover comprises a cover plate having front and rear surfaces and a hollowed region in the rear surface sized to receive the electrical receptacle therein. The cover further comprises a plurality of apertures located through the cover plate sized and located to correspond to the connector openings. The apertures may have edges offset from the connector openings by less than 1/32 of an inch.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention wherein similar characters of reference denote corresponding parts in each view,

FIG. 1 is an perspective view of a light switch cover according to a first embodiment of the present invention being applied to a rocker type switch.

FIG. 2 is a cross-sectional view of the light switch cover of FIG. 1 as taken along the line 2-2.

FIG. 3 is a cross-sectional view of the light switch cover of FIG. 1

FIG. 4 is an exploded perspective view of the light switch cover of FIG. 1.

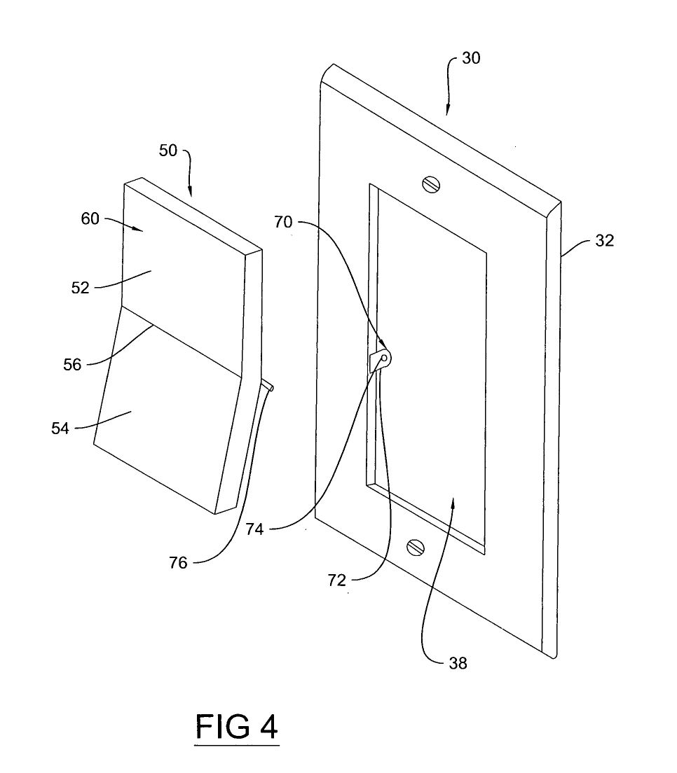

FIG. 5 is an perspective view of an electrical receptacle cover according to a further embodiment of the present invention being applied to an electrical receptacle.

FIG. 6 is a cross-sectional view of the electrical receptacle cover of FIG. 5 as taken along the line 6-6 applied to an electrical receptacle.

### DETAILED DESCRIPTION

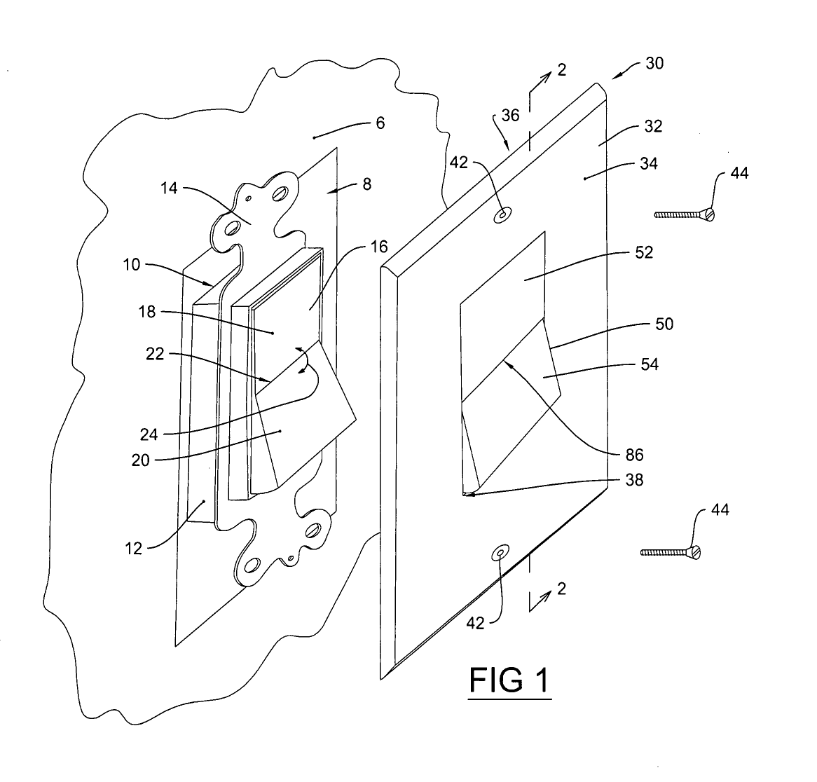

Referring to FIG. 1, a rocker type switch 10 may be located within a hole 8 in a wall 6. The rocker type switch 10 comprises a switch body 12 locatable within the hole 8 in the wall 6 by a plate 14 or other suitable means. The rocker type switch 10 includes a rocking member 16 having first and second switch portions, 18 and 20, respectively. The first and second switch portions 18 and 20 are angularly oriented relative to each other along a division line 22 by an angle, generally indicated at 24. Such angles 24 are conventional on rocker type switch and have ranges commonly know in the art. As illustrated, the rocker type switch may be a decorator (decora) style 15A as are commonly known in the art or any other suitable rocker type switch.

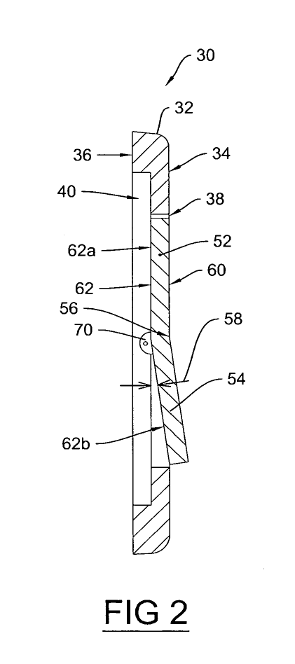

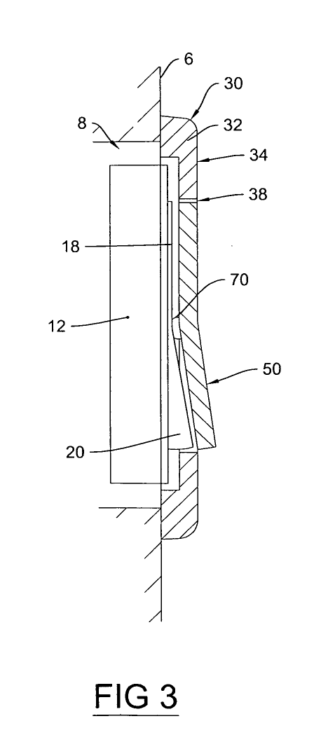

With reference to FIGS. 1 through 3, a cover according to a first embodiment of the invention is shown generally at 30. The cover comprises a cover plate 32 and a rocker plate 50. The cover plate 32 comprises a planar body having front and rear surfaces, 34 and 36, respectively and an aperture 38 extending therethrough. The aperture 38 is sized to correspond to the shape of the rocking member 16 of the rocker type switch 10 when the cover 30 is secured thereto. As illustrated in FIGS. 2 and 3, the rear surface includes a hollow region 40 adapted to receive a rocker type switch 10 therein.

As illustrated in FIG. 1, the cover may include bores 42 sized and located to receive screws or other suitable fasteners 44 therethrough so as to fasten the cover 30 to the wall 6 above the rocker type switch 10. The cover plate will be sized to cover the hole 8 in the wall so as to prevent access thereto. It will be appreciated, that although the cover plate 32 is illustrated as substantially rectangular, other outline shapes may also be utilized such as circular, oval, triangular, heart shaped, maple leaf shaped or any other shape as desired by the user based upon their intended appearance.

The cover 30 includes a rocker plate 50 pivotally located within the aperture 38. The rocker plate 50 is sized so as to have an outline corresponding to the aperture and therefore to correspond to the rocking member 16 of the rocker type switch 10 as well. The rocker plate 50 comprises a substantially planar member having first and second sections 52 and 54, respectively. As illustrated the first and second sections 52 and 54 are substantially similar to each other in size. As illustrated, the rocker plate 50 has a front surface 60 and a rear surface 62. The rocker plate 50 may have a substantially constant thickness such that the front and rear surfaces 60 and 62 have substantially similar profiles. The rear surface 62 may have a profile adapted to closely follow the surface of the rocking member 16 of the rocker type switch 10.

The first and second sections 52 and 54 may be angularly oriented relative to each other about a bisecting line 56. The second section 54 may be angularly oriented relative to the first section 52 such that the rear surface 62b of the second section 54 and the rear surface 62a of the first section for an angle therebetween generally indicated at 58. It will be appreciated that angle 58 will correspond to the angle in the rocking member 16 of the rocker type switch 10. In other embodiments, the rocker plate 50 may have varying thicknesses such that the front surface 60 does not form an angle corresponding to the angle on the rocking member 16 of the rocker type switch 10. It will be appreciated that the rocker plate 50 may be thicker near the bisecting line 56 such that the front surface has a substantially flat or convex profile or any other profile as desired by the user. It will also be appreciated that the rocker plate 50 may be thinner near the bisecting line 56 such that the front surface has a substantially more concave profile.

The rocker plate 50 is supported within the aperture 38 by a pivot 70. As illustrated, the pivot 70 comprises a pair of upstanding supports 72 extending perpendicularly from the cover plate 32 adjacent to the aperture 38. The supports 72 include support bores 74 therein. It will be appreciated that the supports 72 will be spaced apart by a distance sufficient to permit the rocking member 16 to be located therebetween. The pivot 70 also include a pair of opposed pins 76 extending perpendicularly from the rocker plate 50 adjacent to the bisecting line 56. As illustrated the pins 76 may extend from the rear surface 62 of the rocker plate 50. It will be appreciated, however that the pins 76 may extend from the sides of the rocker plate or adjacent to the front surface 60 of the rocker plate. The pins 76 are pivotally receivable within he support bores 74 so as to permit the rocker plate 50 to freely rotate within the aperture 38 about the pins 76. The pins 76 may be locatable within the apertures by permitting the supports 72 to be elastically deformed apart by a distance sufficient to permit the pins 76 to be located within the support bores 74 or by any other known method. It will also be appreciated that other methods of pivotally supporting the rocker plate 50 within the aperture 38 may also be utilized as are commonly known in the art.

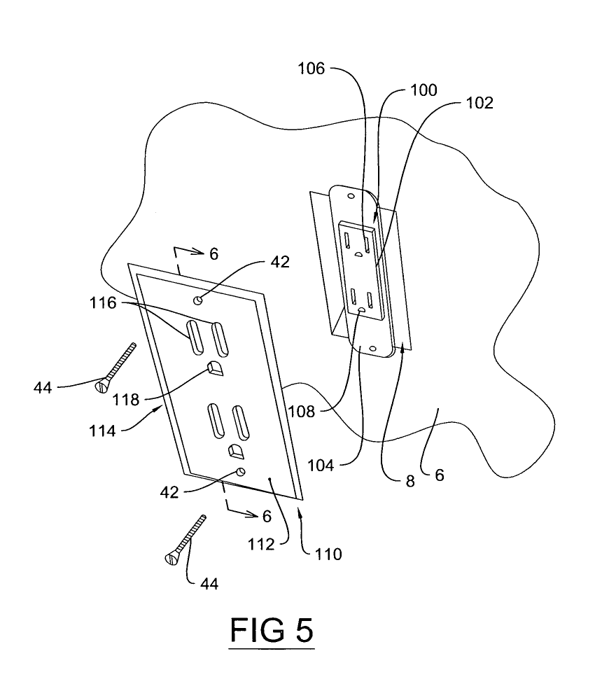

Turning now to FIG. 5, an electrical receptacle 100 may be located within a hole 8 in a wall 6. The electrical receptacle 100 comprises a outlet receptacle body 102 locatable within hole 8 in the wall 6 by a receptacle plate 104. The electrical receptacle 100 includes a plurality off first and second connector openings, 106 and 108, respectively. As illustrated, the electrical receptacle may be a decorator (decora) style 15A as are commonly known in the art or any other suitable receptacle.

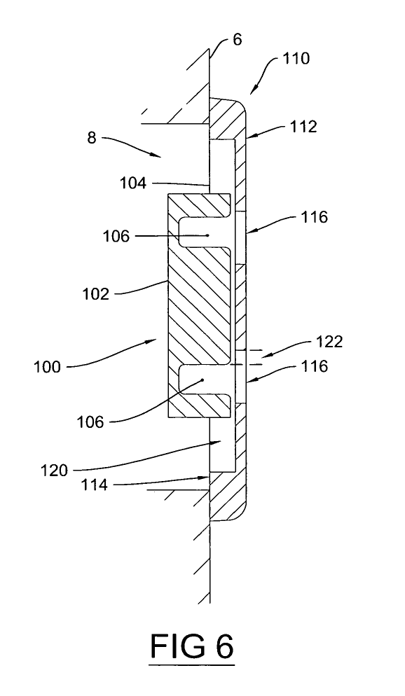

With reference to FIGS. 5 and 6, a cover according to a further embodiment of the invention is shown generally at 110 comprising a planar body having front and rear surfaces, 112 and 114, respectively and a plurality of apertures 116 and 118 extending therethrough. As illustrated in FIG. 6, the rear surface 114 of the cover 110 includes a hollow region 120 adapted to receive the electrical receptacle 100 therein such that the cover 110 substantially covers the electrical receptacle 100 when the cover is secured to the wall 6. The cover may include bores 42 sized and located to receive screws or other suitable fasteners 44 therethrough so as to fasten the cover 30 to the wall 6. The cover plate will be sized to cover the hole 8 in the wall so as to prevent access thereto. It will be appreciated, that although the cover 110 is illustrated as substantially rectangular, other outline shapes may also be utilized such as circular, oval, triangular, heart shaped, maple leaf shaped or any other shape as desired by the user based upon their intended appearance.

The first connector openings 106 may be slot type openings for receiving the blades of a conventional electrical plug. As illustrated, the apertures 116 are sized and located in the cover 110 so as to correspond to the first connector openings 106. The second connector openings 108 may be grounding type openings for receiving and grounding the grounding pin of a conventional electrical plug. Similarly, the second apertures 118 are sized and located in the cover 110 so as to correspond to the second connector openings 108. It will be appreciated that the first and second apertures 116 and 118 may be sized so as to be slightly larger than the respective first and second connector openings 106 and 108 such that the edge of the first and second apertures are offset from the connector openings by a distance generally indicated at 122. This will facilitate the ease of installation of a plug though the cover. It has been found that sizing the offset at less than 1/32 of an inch has been useful although it will be appreciated that other distances may be useful as well.

The materials utilized to form the a cover according to the present disclosure may be of any suitable rigid material such as, by way of non-limiting example, stainless steel, anodized aluminum, plastic, ceramics, glass or mirrors. It will also be appreciated that the material should be selected so as to be electrically non-conductive. Although the above materials are provided for example purposes only, it will be appreciated that many other materials may also be suitable. The materials utilized to form the cover may also be of any color or be readily paintable

While specific embodiments of the invention have been described and illustrated, such embodiments should be considered illustrative of the invention only and not as limiting the invention as construed in accordance with the accompanying claims.

What is claimed is:

1. A cover for a rocker type switch located within a hole in a wall comprising:
a cover plate sized to cover the hole in the wall, said cover plate having an aperture therethrough sized to surround the rocker type switch; and
a rocker plate sized to overlay the rocker type switch pivotally located within said aperture wherein said rocker plate bears against the rocker type switch so as to transmit motion of said rocker plate to the rocker type switch.

2. The cover of claim 1 wherein said aperture has a rectangular shape corresponding to a rectangular outline of the rocker type switch.

3. The cover of claim 1 wherein said rocker plate has first and second planar segments angularly oriented relative to each other.

4. The cover of claim 3 wherein said second planar segment is oriented out of a plane of said first planar segment by an angle corresponding to the rocker type switch.

5. The cover of claim 1 wherein said rocker plate has a back profile shaped to closely engage the rocker type switch.

6. The cover of claim 1 further comprising a pivot between said cover plate and said rocker plate.

7. The cover of claim 6 wherein said pivot comprises a pair of opposed pins extending from said rocker plate, said aperture having a pair of bores sized to receive said pins therein.

8. The cover of claim 7 wherein said bores are located in plates extending perpendicularly from said aperture.

9. The cover of claim 8 wherein said bores are located adjacent to opposed sides of said angle.

10. The cover of claim 1 wherein said cover plate has first and second mounting bores sized and located to receive screws therethrough to secure said cover to the wall.

11. A cover for an electrical receptacle having a plurality of connector openings located within a hole in a wall, the cover comprising:
a cover plate having front and rear surfaces, said cover plate having a hollowed region in said rear surface sized to receive the electrical receptacle therein; and
a plurality of apertures located through said cover plate, said plurality of apertures being sized and located to correspond to the connector openings.

12. The cover of claim 11 wherein said apertures have fixed locations within said cover plate.

13. The cover of claim 11 wherein said apertures have edges offset from the connector openings by less than 1/32 of an inch.
